(19) United States
(12) Patent Application Publication
(10) Pub. No.: US 2021/0028349 A1
(43) Pub. Date: Jan. 28, 2021

(54) INTEGRATED CIRCUITS WITH MAGNETIC TUNNEL JUNCTION MEMORY CELLS AND METHODS FOR PRODUCING THE SAME

(71) Applicant: Globalfoundries Singapore Pte. Ltd., Singapore (SG)

(72) Inventors: Kah Wee Gan, Singapore (SG); Benfu Lin, Singapore (SG); Chim Seng Seet, Singapore (SG)

(21) Appl. No.: 16/521,172

(22) Filed: Jul. 24, 2019

(51) Int. Cl. H01L 43/02; G11C 11/16; H01L 27/22; H01L 43/10; H01L 43/12

(52) U.S. Cl. CPC H01L 43/02; G11C 11/161; H01L 43/12; H01L 43/10; H01L 27/222

(57) ABSTRACT

Integrated circuits and methods of producing the same are provided. In an exemplary embodiment, an integrated circuit includes a contact overlying a substrate, and a bottom electrode overlying the contact. The bottom electrode is in electrical communication with the contact, and the bottom electrode has a bottom electrode upper surface with a bottom electrode upper surface area. A magnetic tunnel junction memory cell overlies the bottom electrode and is in electrical communication with the bottom electrode. The magnetic tunnel junction memory cell has an MTJ bottom surface with an MTJ bottom surface area that is greater than the bottom electrode surface area.

### TECHNICAL FIELD

The technical field generally relates to integrated circuits with magnetic tunnel junction memory cells and methods of producing the same, and more particularly relates to integrated circuits with magnetic tunnel junction memory cells that overlie a bottom electrode that is smaller than the magnetic tunnel junction memory cell.

### BACKGROUND

Non-volatile memory cells retain their stored data, even when the power supply is removed. Therefore, non-volatile memory cells are desirable for devices that may be turned on and off during normal use. A magnetic tunnel junction memory cell is a structure that stores information even when the power is turned off, because the electrical resistance of the memory cell depends on the orientation of magnetization between a pinned magnetic layer and a free magnetic layer. The magnetic tunnel junction memory cell is typically positioned between a bottom electrode and a top electrode. During manufacture, the bottom electrode may occasionally be “shorted” to some layers of the magnetic tunnel junction that are above the bottom layer, and this short impairs or destroys the operation of the magnetic tunnel junction memory cell. The small size of the components involved make it difficult to effectively prevent the shorts.

Accordingly, it is desirable to provide integrated circuits and methods of producing the same with magnetic tunnel junction memory cells that have fewer shorts with the underlying bottom electrode. In addition, it is desirable to provide integrated circuits with magnetic tunnel junction memory cells that have structures that minimize the chances of forming shorts between the various layers of the magnetic tunnel junction memory cell and the bottom electrode, and methods for producing the same. Furthermore, other desirable features and characteristics of the present embodiments will become apparent from the subsequent detailed description and the appended claims, taken in conjunction with the accompanying drawings and this background.

### BRIEF SUMMARY

Integrated circuits and methods of producing the same are provided. In an exemplary embodiment, an integrated circuit includes a contact overlying a substrate, and a bottom electrode overlying the contact. The bottom electrode is in electrical communication with the contact, and the bottom electrode has a bottom electrode upper surface with a bottom electrode upper surface area. A magnetic tunnel junction memory cell overlies the bottom electrode and is in electrical communication with the bottom electrode. The magnetic tunnel junction memory cell has an MTJ bottom surface with an MTJ bottom surface area that is greater than the bottom electrode surface area.

An integrated circuit is provided in another exemplary embodiment. The integrated circuit includes a substrate and a contact overlying the substrate. A bottom electrode ovelies the contact, where the bottom electrode is in electrical communication with the contact, and where the bottom electrode has a bottom electrode upper surface. A magnetic tunnel junction memory cell overlies all of the bottom electrode and the bottom electrode upper surface.

A method of producing an integrated circuit is provided in another embodiment. The method includes forming a contact dielectric layer overlying a substrate, and forming a contact through the contact dielectric layer. A bottom electrode is formed overlying the contact, where the bottom electrode is in electrical communication with the contact, and where the bottom electrode has a bottom electrode upper surface with a bottom electrode upper surface area. A magnetic tunnel junction memory cell is formed overlying the bottom electrode and in electrical communication with the bottom electrode. The magnetic tunnel junction memory cell has an MTJ bottom surface with an MTJ bottom surface area that is greater than the bottom electrode upper surface area.

### BRIEF DESCRIPTION OF THE DRAWINGS

The present embodiments will hereinafter be described in conjunction with the following drawing figures, wherein like numerals denote like elements, and wherein:

FIGS. 1-7 are cross sectional views of embodiments of an integrated circuit, and methods for producing the same; and

FIG. 8 is an exploded view of a portion of an embodiment of an integrated circuit.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description. Embodiments of the present disclosure are generally directed to integrated circuits and methods for fabricating the same. The various tasks and processes described herein may be incorporated into a more comprehensive procedure having additional processes or functionality not described in detail herein. In particular, various processes in the manufacture of integrated circuits are well-known and so, in the interest of brevity, many conventional processes will only be mentioned briefly herein or will be omitted entirely without providing the well-known process details.

An integrated circuit includes a bottom electrode underlying a magnetic tunnel junction memory cell. The size of the bottom electrode is reduced such that the bottom of the magnetic tunnel junction memory cell overlaps the edges of the bottom electrode. As such, it is unlikely that portions of the bottom electrode will extend up the side of the magnetic tunnel junction memory cell.

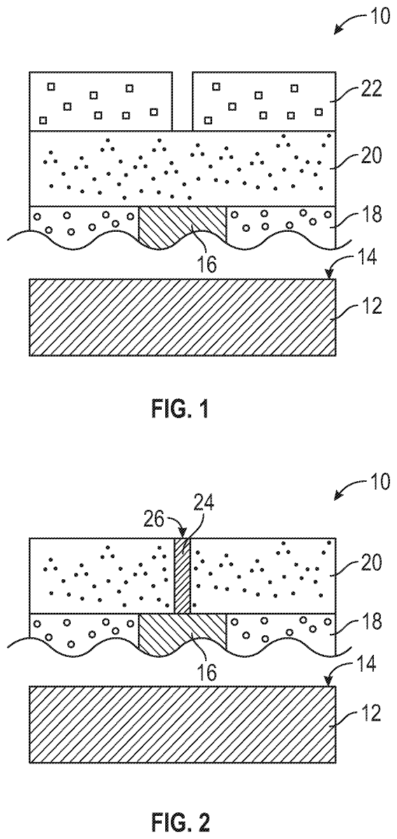

Reference is made to FIG. 1, where one possible manufacturing process is illustrated and described. It is to be understood that several other possible manufacturing processes could be utilized to produce comparable structures, and the exemplary embodiment illustrated in FIGS. 1-8 provides a general roadmap for those skilled in the art. An integrated circuit 10 includes a substrate 12 formed of a semiconductor material. As used herein, the term “semiconductor material” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. As referred to herein, a material that includes a recited element/compound includes the recited element/compound in an amount of at least about 10 weight percent or more based on the total weight of the referenced component or material, unless otherwise indicated. In many embodiments, the substrate 12 primarily includes a monocrystalline semiconductor material. The term “primarily includes,” as used herein, means the specified material is present in the specified component at a concentration of at least about 50 weight percent, based on a total weight of the component. The substrate 12 may be a bulk silicon wafer (as illustrated) or may be a thin layer of silicon on an insulating layer (commonly known as silicon-on-insulator or SOI, not illustrated) that, in turn, is supported by a carrier wafer. The substrate 12 has a substrate surface 14 that is depicted horizontally in FIG. 1, and the substrate surface 14 may be used as a spatial reference herein.

The integrated circuit 10 may include many electronic components formed in, on, and/or overlying the substrate 12. Most of these electronic components are not depicted in the FIGS. to simplify the drawings and description for clarity. As such, the area underlying the wavy line and overlying the substrate 12 in the FIGS. includes electronic components that are not critical to the specific features of this description. An electrically conductive component overlies the substrate 12, where the electrically conductive component is an interconnect 16 in the illustrated embodiment. The electrically conductive component may be one or more structures other than an interconnect 16 in alternate embodiments, where the underlying electrically conductive component is in electrical communication with other electronic components used for operation of a memory cell.

As used herein, the term “overlying” means “over such that an intervening layer may lie between the overlying component (the interconnect 16 in this example) and the underlying component (the substrate 12 in this example), or “on” such that the overlying component physically contacts the underlying component. Moreover, the term “overlying” means a vertical line passing through the overlying component also passes through the underlying component, such that at least a portion of the overlying component is directly over at least a portion of the underlying component. It is understood that the integrated circuit 10 may be moved such that the relative “up” and “down” positions change, and the integrated circuit 10 can be operated in any orientation. Spatially relative terms, such as “top”, “bottom”, “over” and “under” are made in the context of the orientation of FIGS. 1-7. It is to be understood that spatially relative terms refer to the orientation in FIGS. 1-7, so if the integrated circuit 10 were to be oriented in another manner the spatially relative terms would still refer to the orientation depicted in FIGS. 1-7. Thus, the exemplary terms “over” and “under” remain the same even if the device is twisted, flipped, or otherwise oriented other than as depicted in FIGS. 1-7.

As used herein, an “electrically insulating material” is a material with a resistivity of about 1×10⁴ ohm meters or more, an “electrically conductive material” is a material with a resistivity of about 1×10⁻⁴ ohm meters or less, and an “electrically semiconductive material” is a material with a resistivity of from about more than 1×10⁻⁴ ohm meters to less than about 1×10⁴ ohm meters.

An interconnect dielectric 18 is positioned overlying the substrate 12 and adjacent to the interconnect 16. The interconnect dielectric 18 (and other dielectrics described below) may include a wide variety of electrically insulating materials in various embodiments. For example, un-doped silicate glass (USG), silicon nitride, silicon oxynitride, silicon dioxide, low K dielectric materials, combinations thereof, or other insulating materials may be used. In an exemplary embodiment, silicon dioxide is deposited by chemical vapor deposition using silane and oxygen, but other techniques and/or materials are utilized in alternate embodiments. A contact dielectric 20 overlies the interconnect 16 and the interconnect dielectric 18. The contact dielectric 20 may be the same material as the interconnect dielectric 18 in some embodiments, but the contact dielectric 20 may be a different electrically insulating material in other embodiments. The distinction between the interconnect dielectric 18 and the contact dielectric 20 may be difficult to identify in the integrated circuit 10, but the interconnect dielectric 18 and contact dielectric 20 may be separately formed and are depicted as separate structures herein.

A contact photoresist 22 is formed and patterned overlying the contact dielectric 20. The contact photoresist 22 (and other photoresist layers described below) may be deposited by spin coating, and patterned by exposure to light or other electromagnetic radiation through a mask with transparent sections and opaque sections. The light causes a chemical change in the photoresist such that either the exposed portion or the non-exposed portion can be selectively removed. The desired locations may be removed with an organic solvent, and the contact photoresist 22 remains overlying the other areas of the contact dielectric 20. The contact photoresist 22 (and other photoresist layers described below) may optionally include a top and/or bottom anti-reflective coating and/or a hard mask (not illustrated). Many anti-reflective coatings are available, including inorganic and organic compounds, such as titanium nitride or organosiloxanes. Titanium nitride may be deposited by chemical vapor deposition using tetramethylamidotitanium and nitrogen trifluoride, and organosiloxanes may be deposited by spin coating. Anti-reflective coatings may improve the accuracy and critical dimensions during photoresist patterning. Silicon nitride may be used as a hard mask, where silicon nitride can be formed by low pressure chemical vapor deposition using ammonia and dichlorosilane.

Reference is made to FIG. 2. A via (not individually illustrated) is etched in the exposed areas of the contact photoresist 22, and then the contact photoresist 22 may be removed, such as with an oxygen containing plasma. The contact dielectric 20 may be etched with a reactive ion etch using a wide variety of materials, such as carbon tetrachloride for embodiments where the contact dielectric 20 primarily includes silicon dioxide. A contact 24 is then formed in the via, where the contact 24 may be about perpendicular to the substrate surface 14. The contact 24 is in electrical communication with the interconnect 16, so the contact 24 may be formed through the contact dielectric 20. In an exemplary embodiment, the contact 24 includes an adhesion layer, a barrier layer, and a plug (not individually illustrated) which may be sequentially deposited. In an exemplary embodiment, an adhesion layer of titanium is formed by low pressure chemical vapor deposition of titanium pentachloride, a barrier layer of titanium nitride is formed by chemical vapor deposition of titanium tetrabromide and ammonia, and a plug of tungsten is formed by chemical vapor deposition of tungsten hexafluoride and hydrogen. As such, the contact 24 may include tungsten, and may primarily include tungsten in some embodiments. The contact 24 includes a contact upper surface 26 that has a contact upper surface area. Contacts formed form other materials are also possible, such as copper or other conductive materials.

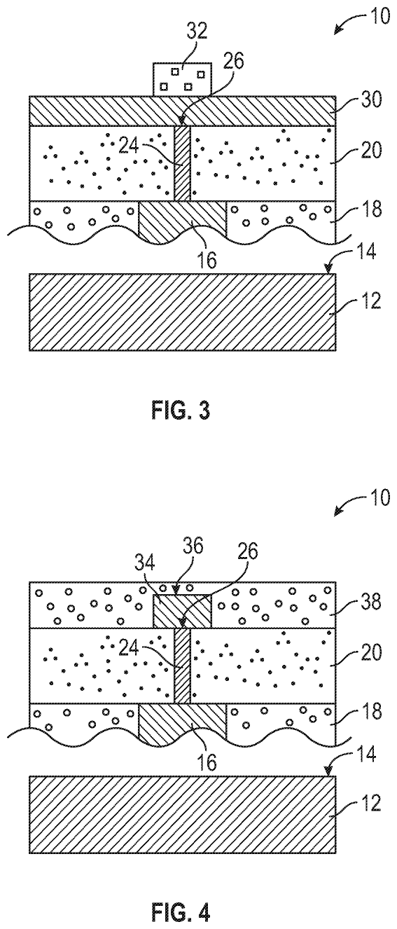

A bottom electrode layer 30 is formed overlying the contact dielectric 20 and the contact 24, as illustrated in an exemplary embodiment in FIG. 3. The bottom electrode layer 30 is formed from an electrically conductive material, such as tantalum nitride, copper, aluminum, or other electrically conductive materials. Tantalum nitride may be deposited by chemical vapor deposition using tantalum pentafluoride and nitrogen, for example, but other materials or techniques of forming the bottom electrode layer 30 are also possible. The bottom electrode layer 30 may be formed in direct physical contact with the contact 24. A bottom electrode photoresist 32 is formed and patterned overlying the bottom electrode layer 30.

A bottom electrode 34 is formed by anisotropically etching the bottom electrode layer 30 where it is not protected by the bottom electrode photoresist 32, as illustrated in FIG. 4 with continuing reference to FIG. 3. As such, the bottom electrode 34 is lithographically patterned and formed from the bottom electrode layer 30. The bottom electrode 34 may be in direct physical contact with the contact 24, and the bottom electrode 34 is in electrical communication with the contact 24. The bottom electrode 34 also overlies the contact 24. The bottom electrode 34 has a bottom electrode upper surface 36 with a bottom electrode upper surface area. In an exemplary embodiment, the bottom electrode upper surface area is greater than the contact upper surface area, and the bottom electrode 34 overlaps the contact upper surface 26 at all points of the contact upper surface 26, so the bottom electrode extends beyond the contact upper surface 26 in all directions in a plane parallel with the substrate surface 14. A bottom electrode dielectric layer 38 is formed overlying the bottom electrode 34 and the contact dielectric 20, where the bottom electrode dielectric layer 38 is electrically insulating, as described above for dielectrics.

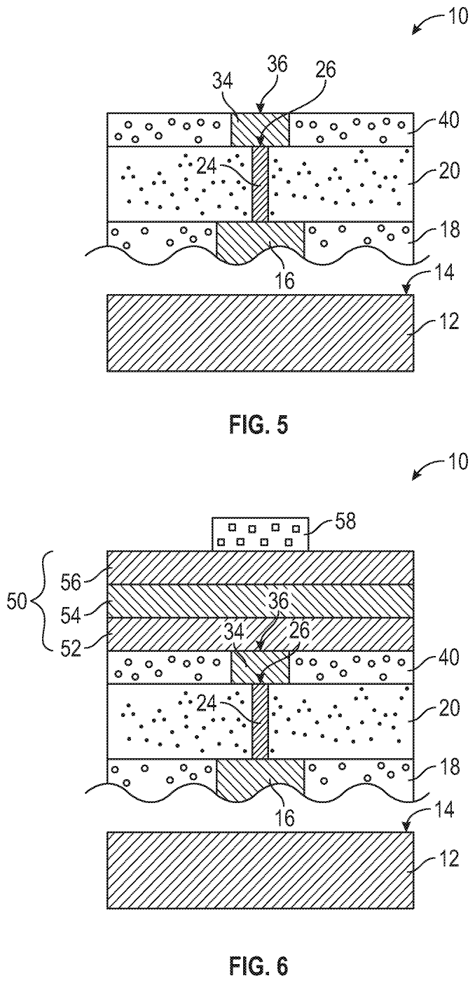

FIG. 5 illustrates an exemplary embodiment where the bottom electrode dielectric layer 38 is reduced and smoothed, such as by planarized by chemical mechanical planarization, to produce the bottom electrode dielectric 40, with continuing reference to FIG. 4. The bottom electrode dielectric 40 is the reduced and smoothed remnants of the bottom electrode dielectric layer 38. The bottom electrode dielectric 40 is reduced to expose the bottom electrode upper surface 36. In some embodiments, the bottom electrode 34 may serve as a stop point for the planarization process in the reduction of the bottom electrode dielectric layer 38.

A magnetic tunnel junction (MTJ) stack layer 50 is formed overlying the bottom electrode dielectric 40 and also overlying the bottom electrode 34. The MTJ stack layer 50 includes a plurality of individual material layers. In one embodiment, MTJ stack layer 50 includes a preliminary pinned layer 52 overlying the bottom electrode 34, a preliminary tunnel barrier layer 54 overlying the preliminary pinned layer 52, and a preliminary free layer 56 overlying the preliminary tunnel barrier layer 54. Each of the preliminary pinned layer 52, the preliminary tunnel barrier layer 54, and/or the preliminary free layer 56 may include sublayers (not individually illustrated) in various embodiments. Furthermore, the MTJ stack layer 50 may optionally include additional layers not specifically illustrated, including but not limited to one or more seed layer(s), coupling layer(s), transition layer(s), capping layer(s), and other layers. The preliminary pinned layer 52 and the preliminary free layer 56 are reversed in alternate embodiments, where the preliminary pinned layer 52 overlies the preliminary tunnel barrier layer 54 and the preliminary free layer 56 underlies the preliminary tunnel barrier layer 54, but the preliminary tunnel barrier layer 54 is always positioned between the preliminary pinned layer 52 and the preliminary free layer 56.

The preliminary tunnel barrier layer 54 may be thin, such as from about 1 to about 2 nanometers (nm) in thickness, and is an electrical insulator in an exemplary embodiment. The preliminary tunnel barrier layer 54 includes magnesium oxide in an exemplary embodiment, but the preliminary tunnel barrier layer 54 may include silicon dioxide or other electrical insulating materials in various embodiments. The preliminary tunnel barrier layer 54 may be deposited by sputtering magnesium followed by plasma oxidation. The preliminary free layer 56 includes cobalt iron boron (CoFeB) in an exemplary embodiment, and the preliminary pinned layer 52 includes platinum manganese (PtMn) in one embodiment, but these layers may include other materials such as iridium manganese (IrMn), nickel manganese (NiMn), iron manganese (FeMn), CoFeB, or other materials in alternate embodiments. The preliminary free and pinned layers 56, 52 may be deposited by ion beam sputtering, but other techniques may be used in alternate embodiments. A magnetic tunnel junction photoresist 58 is formed and patterned overlying the MTJ stack layer 50.

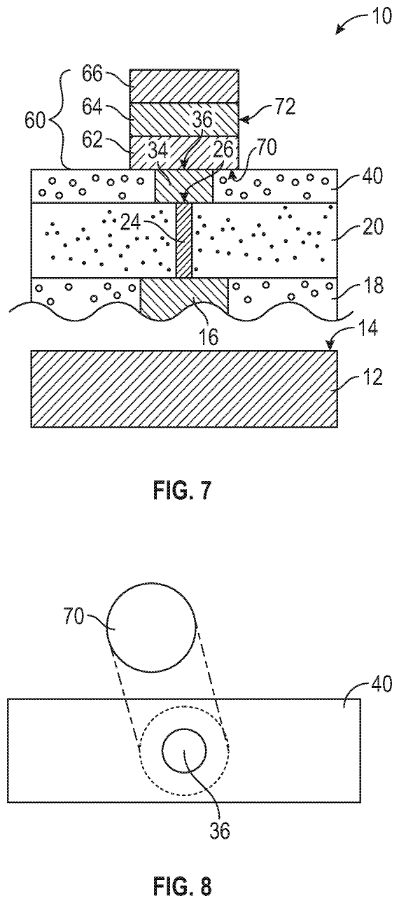

The magnetic tunnel junction memory cell 60 is formed by anisotropically etching the layers of the magnetic tunnel junction stack layer 50 where exposed by the magnetic tunnel junction photoresist 58, as illustrated in FIG. 7 with continuing reference to FIG. 6. The various layers of the magnetic tunnel junction stack layer 50 may be sequentially etched using the same or different etchants and/or etch techniques. The magnetic tunnel junction memory cell 60 includes a pinned layer 62 formed from the preliminary pinned layer 52, a tunnel barrier layer 64 formed from the preliminary tunnel barrier layer 54, and a free layer 66 formed from the preliminary free layer 56. The properties and relationship of the pinned layer 62, the tunnel barrier layer 64, and the free layer 66 are the same as for the preliminary pinned layer 52, the preliminary tunnel barrier layer 54, and the preliminary free layer 56 described above.

The magnetic tunnel junction memory cell 60 has an MTJ bottom surface 70 with an MTJ bottom surface area, as illustrated in FIG. 8 with continuing reference to FIGS. 6 and 7. FIG. 8 represents a top view of the bottom electrode 34 and the bottom electrode dielectric 40, and a view of the MTJ bottom surface 70 with dots indicating where the MTJ bottom surface 70 is positioned overlying the bottom electrode 34 and bottom electrode dielectric 40. The dashed lines illustrates how the MTJ bottom surface 70 is positioned. The MTJ bottom surface 70 is in electrical communication with the bottom electrode 34, and the MTJ bottom surface 70 is in direct physical contact with the bottom electrode 34 in some embodiments, such as in direct physical contact with the bottom electrode upper surface 36. The MTJ bottom surface area is greater than the bottom electrode upper surface area, and the MTJ bottom surface 70 may overlap the bottom electrode upper surface 36 at all points of the bottom electrode upper surface 36 so the MTJ bottom surface 70 extends past the bottom electrode upper surface 36 at all points of the bottom electrode upper surface 36 in a plane that is about parallel to the substrate surface 14. As such, the magnetic tunnel junction memory cell 60 overlies all of the bottom electrode 34 and the bottom electrode upper surface 36. The MTJ bottom surface 70 overlaps the bottom electrode 34 in a plane parallel to the substrate surface in an embodiment, so no portion of the bottom electrode 34 is exposed to extend up an MTJ side surface 72. This prevents or at least minimizes shorts between the bottom electrode 34 and portions of the magnetic tunnel junction memory cell 60 other than the MTJ bottom surface 70.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

1. An integrated circuit comprising:
a substrate having a substrate surface;
a contact overlying the substrate;
a bottom electrode overlying the contact, the bottom electrode in electrical communication with the contact, the bottom electrode having a bottom electrode upper surface, and the bottom electrode upper surface having a bottom electrode upper surface area; and
a magnetic tunnel junction memory cell overlying the bottom electrode, the magnetic tunnel junction memory cell in electrical communication with the bottom electrode, the magnetic tunnel junction memory cell comprises an MTJ bottom surface with an MTJ bottom surface area, the MTJ bottom surface area is greater than the bottom electrode upper surface area, and the MTJ bottom surface extends past the bottom electrode upper surface at all points of the bottom electrode upper surface in a plane that is about parallel to the substrate surface.

2. The integrated circuit of claim 1 wherein the MTJ bottom surface overlaps the bottom electrode at all points of the bottom electrode upper surface.

3. The integrated circuit of claim 1 wherein the contact comprises tungsten.

4. The integrated circuit of claim 1 wherein the bottom electrode directly contacts the contact.

5. The integrated circuit of claim 1 wherein the magnetic tunnel junction memory cell directly contacts the bottom electrode.

6. The integrated circuit of claim 1 wherein the magnetic tunnel junction memory cell comprises a pinned layer that is magnetic, a free layer that is magnetic, and a tunnel barrier layer positioned between the pinned layer and the free layer, and the tunnel barrier layer is non-magnetic.

7. The integrated circuit of claim 1 wherein the contact comprises a contact upper surface with a contact upper surface area, and the contact upper surface area is less than the bottom electrode upper surface area.

8. An integrated circuit comprising:
a substrate having a substrate surface;
a contact overlying the substrate;
a bottom electrode overlying the contact, the bottom electrode in electrical communication with the contact, and the bottom electrode having a bottom electrode upper surface; and
a magnetic tunnel junction memory cell overlying the bottom electrode, the magnetic tunnel junction memory cell overlies all of the bottom electrode upper surface, and the magnetic tunnel junction memory cell has a bottom surface that extends past the bottom electrode upper surface at all points of the bottom electrode upper surface in a plane that is about parallel to the substrate surface.

9. The integrated circuit of claim 8 wherein the magnetic tunnel junction memory cell overlaps the bottom electrode at all points of the bottom electrode.

10. The integrated circuit of claim 8 wherein the bottom electrode directly contacts the contact.

11. The integrated circuit of claim 8 wherein the magnetic tunnel junction memory cell directly contacts the bottom electrode.

12. The integrated circuit of claim 8 wherein the magnetic tunnel junction memory cell comprises a pinned layer that is magnetic, a free layer that is magnetic, and a tunnel barrier layer positioned between the pinned layer and the free layer, and the tunnel barrier layer is non-magnetic.

13. A method of producing an integrated circuit, the method comprising:
forming a contact dielectric layer overlying a substrate;
forming a contact through the contact dielectric layer;
forming a bottom electrode overlying the contact, wherein the bottom electrode is in electrical communication with the contact, and the bottom electrode has a bottom electrode upper surface with a bottom electrode upper surface area; and
forming a magnetic tunnel junction memory cell overlying the bottom electrode, wherein the magnetic tunnel junction memory cell is in electrical communication with the bottom electrode, wherein the magnetic tunnel junction memory cell comprises an MTJ bottom surface with an MTJ bottom surface area, the MTJ bottom surface area is greater than the bottom electrode upper surface area, and the MTJ bottom surface extends past the bottom electrode upper surface at all points of the bottom electrode upper surface in a plane that is about parallel to the substrate surface.

14. The method of claim 13 wherein forming the bottom electrode comprises:
forming a bottom electrode layer overlying the contact dielectric layer and the contact; and
lithographically patterning the bottom electrode from the bottom electrode layer.

15. The method of claim 14 wherein forming the bottom electrode further comprises:
forming a bottom electrode dielectric layer adjacent to and overlying the bottom electrode; and
planarizing the bottom electrode dielectric layer to expose the bottom electrode.

16. The method of claim 13 wherein forming the magnetic tunnel junction memory cell comprises:
forming the magnetic tunnel junction memory cell such that the magnetic tunnel junction memory cell overlaps the bottom electrode at all points of the bottom electrode

17. The method of claim 13 wherein forming the magnetic tunnel junction memory cell comprises:
forming the magnetic tunnel junction memory cell such that the magnetic tunnel junction memory cell overlies all of the bottom electrode upper surface.

18. The method of claim 13 wherein forming the magnetic tunnel junction memory cell comprises:
forming a pinned layer that is magnetic;
forming a tunnel barrier layer overlying the pinned layer, wherein the tunnel barrier layer is non-magnetic; and
forming a free layer overlying the tunnel barrier layer, wherein the free layer is magnetic.

19. The method of claim 13 wherein forming the bottom electrode comprises:
forming the bottom electrode in direct contact with the contact.

20. The method of claim 13 wherein forming the magnetic tunnel junction memory cell comprises:
forming the magnetic tunnel junction memory cell in direct contact with the bottom electrode.
